(19) United States
(12) Patent Application Publication
(10) Pub. No.: US 2026/0105230 A1
(43) Pub. Date: Apr. 16, 2026

(54) COLLABORATIVE CONE OF INFLUENCE LOGIC DEBUGGING

(71) Applicant: International Business Machines Corporation, Armonk, NY (US)

(72) Inventors: Arun Joseph, WHITEFIELD (IN); Rajeev B R, Bengaluru (IN); Pradeep Joy, Thrissur (IN); Balaji Pulluru, Tirupati (IN); Matthias Klein, POUGHKEEPSIE, NY (US); Wolfgang Roesner, Austin, TX (US)

(73) Assignee: International Business Machines Corporation, Armonk, NY (US)

(21) Appl. No.: 18/911,392

(22) Filed: Oct. 10, 2024

(51) Int. Cl. G06F 30/327; G06F 30/31

(52) U.S. Cl. CPC G06F 30/327; G06F 30/31

(57) ABSTRACT

In a computer-implemented technique of collaborative cone of influence debugging across use-cases and users, a server receives, from a client, a signal request specifying a signal of interest in a register-transfer level (RTL) logic design. Based on the signal request, server processing circuitry parses the RTL logic design and generates a tree data structure representing at least a cone of influence of the signal of interest. The server processing circuitry transmits to the client a signal response including a portion of the tree data structure. The portion of the tree data structure specifies, for each node among a plurality of nodes in the cone of influence of the signal of interest, at least a filename of a hardware description language (HDL) file in which a corresponding signal is instantiated, a line of HDL source code from the HDL file instantiating the corresponding signal, and any child of the node.

### BACKGROUND OF THE INVENTION

The present invention relates in general to integrated circuit design, and more specifically, to debugging integrated circuit designs.

Electronic Design Automation (EDA) tools have become indispensable in modern semiconductor design, enabling the creation and verification of complex integrated circuits (ICs). Among these tools, those specifically designed for debugging logic designs play a crucial role in identifying and resolving errors within the digital circuitry of ICs.

While EDA tools have evolved significantly over the years, several key approaches and techniques have emerged as standard practices. Simulation, including both functional and timing simulation, is used to model the behavior of a design and assess its performance. Formal verification techniques, such as equivalence checking and property checking, ensure the correctness of the design. Static timing analysis (STA) identifies potential timing violations, while hardware acceleration speeds up simulation and verification processes. Visualization tools provide graphical interfaces to aid in understanding and debugging the design. Advanced techniques like profiling, traceability, and assertion-based verification further enhance the debugging capabilities of EDA tools.

Despite these advancements, there is a continuing need for improvements in EDA tools, including in the efficiency and usability of debugging tools.

### SUMMARY OF THE INVENTION

The present application discloses a technique of collaborative hardware logic cone of influence debugging across use-cases and users.

According to one or more embodiments of a computer-implemented technique of debugging, a server receives, from a client, a signal request specifying a signal of interest in a register-transfer level (RTL) logic design. Based on the signal request, server processing circuitry of the server parses the RTL logic design and generates a tree data structure representing at least a cone of influence of the signal of interest. The server processing circuitry transmits to the client a signal response including a portion of the tree data structure. The portion of the tree data structure specifies, for each node among a plurality of nodes in the cone of influence of the signal of interest, at least a filename of a hardware description language (HDL) file in which a corresponding signal is instantiated, a line of HDL source code from the HDL file instantiating the corresponding signal, and any child of the node.

### BRIEF DESCRIPTION OF THE DRAWINGS

FIG. 1 is a high-level block diagram of an exemplary data processing environment in accordance with one or more embodiments;

FIG. 2 is a high-level logical flowchart of an integrated circuit design, verification, and fabrication process in accordance with one or more embodiments;

FIG. 3 is a high-level block diagram of an exemplary architecture of a debugging tool in accordance with one or more embodiments;

FIG. 4 is a representation of a portion of a register-transfer level (RTL) logic design including a set of source latches, a set of sink latches, and connecting combinational logic in accordance with one or more embodiments;

FIG. 5 is a high-level logical diagram of an exemplary process by which a server component of a debugging tool services signal requests of a client component of the debugging tool in accordance with one or more embodiments;

FIG. 6 is a high-level logical diagram of an exemplary process by which a client component of a debugging tool processes signal responses of a server component of the debugging tool in accordance with one or more embodiments;

FIG. 7 illustrates an exemplary graphical user interface window in which hardware definition language (HDL) defining a portion of a RTL logic design can be viewed and edited in accordance with one or more embodiments;

FIG. 8 depicts an exemplary context window through which a context of a signal of interest can be accessed in accordance with one or more embodiments;

FIG. 9 illustrates an exemplary graphical cone of influence (COI) presentation window for presenting a graphical representation of a COI of a signal of interest in a logic design in accordance with one or more embodiments;

FIG. 10 depicts an exemplary textual COI presentation window for presenting a textual representation of a COI of a signal of interest in a logic design in accordance with one or more embodiments;

FIG. 11 illustrates a graphical representation of the deepest cone of logic COI of a signal of interest in a logic design in accordance with one or more embodiments;

FIG. 12 depicts another exemplary cone of influence (COI) presentation window for presenting a graphical representation of a COI of a signal of interest in a logic design in accordance with one or more embodiments; and

FIG. 13 illustrates another exemplary graphical user interface window in which HDL defining a portion of a RTL logic design can be viewed and edited in accordance with one or more embodiments.

In accordance with common practice, various features illustrated in the drawings may not be drawn to scale. Accordingly, dimensions of the various features may be arbitrarily expanded or reduced for clarity. In addition, some of the drawings may not depict all of the components of a given system, method, or device. Finally, like reference numerals may be used to denote like or corresponding features in the specification and figures.

### DETAILED DESCRIPTION OF ILLUSTRATIVE EMBODIMENT

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

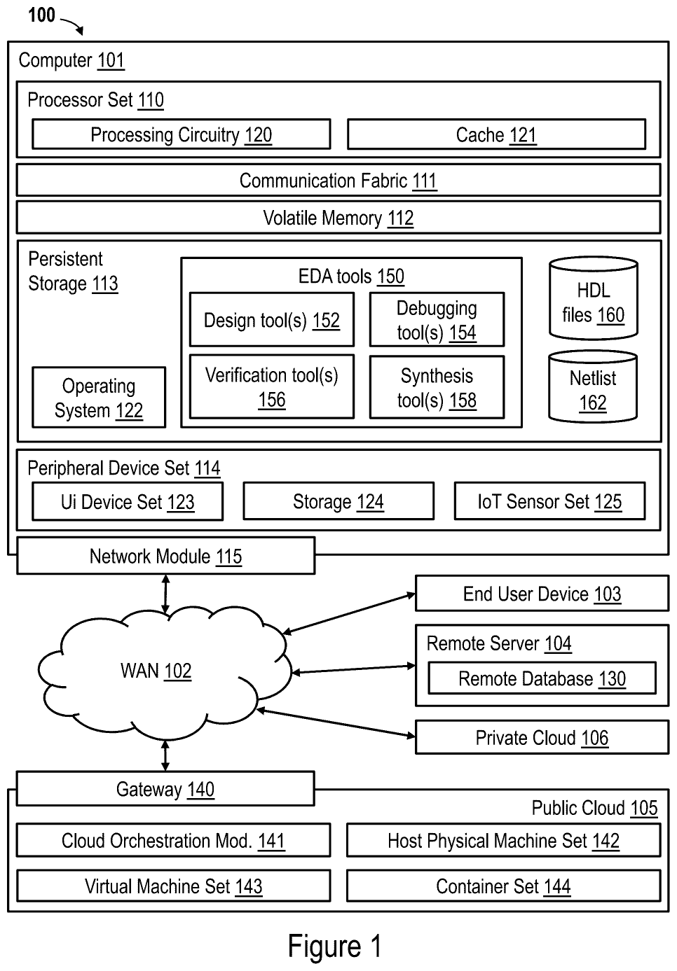

With reference now to FIG. 1, computing environment 100 contains an example of an environment for the execution of at least some of the computer code, such as electronic design automation (EDA) tools 150, involved in performing the inventive methods. In addition, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and other code and data), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one or more computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be implemented in EDA tools 150 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet-of-Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 Is any wide area network (for example, the Internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the Internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Those of ordinary skill in the art will appreciate that the architecture and components of a data processing environment can vary between embodiments. Accordingly, the exemplary computing environment 100 given in FIG. 1 is not meant to imply architectural limitations with respect to the claimed invention.

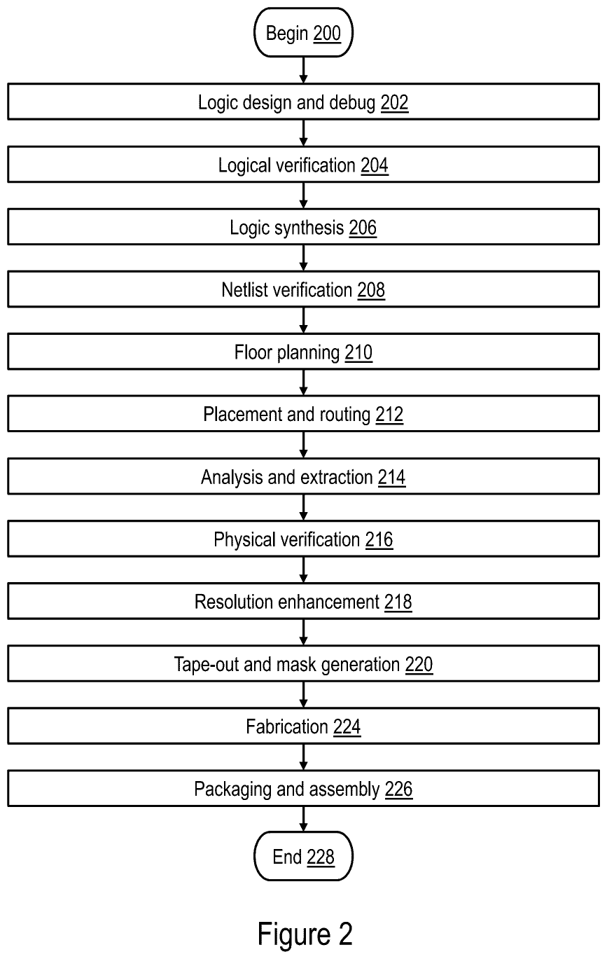

Referring now to FIG. 2, there is depicted a high-level logical flowchart of an integrated circuit design, verification, and fabrication process in accordance with one or more embodiments. The depicted process may be performed, in part, through the use of EDA tools 150, which may include, for example, design tool(s) 152, debugging tool(s) 154, verification tool(s) 156, and synthesis tool(s) 158. Those skilled in the art will appreciate that many of the steps of the depicted process can be performed contemporaneously and/or in a different order than illustrated, and further, may be performed iteratively. It will also be appreciated that for large-scale designs, it is typical for the overall design to be decomposed into multiple smaller units or entities, for which many of the illustrated steps can be separately performed. In the industry, it is also common for multiple parties to separately perform at least some of the illustrated steps and combine the separate work of the multiple parties through inter-party licensing of intellectual property (IP) blocks and/or contract manufacturing.

The process of FIG. 2 begins at block 200 and then proceeds to bock 202, which illustrates a logic design step 202. In step 202, human and/or automated (e.g., artificial intelligence (AI)) circuit designer(s) may specify an initial design for an integrated circuit using one or more design tool(s) 152. The specification for the integrated circuit may be expressed, for example, within hardware description language (HDL) files 160 utilizing a HDL such as Very High Speed Integrated Circuit Hardware Description Language (VHDL), Verilog, SystemVerilog, SystemC, MyHDL or OpenVera. Those skilled in the art will appreciate that EDA tools 150 may transform the HDL description into one or more lower level design description such as a logic-level RTL description, a gate-level description, a layout-level description, or a mask-level description. Each succeeding lower level of design representation provides more specific details for a particular integrated circuit implementation of the design. During logic design step 202, the design can be decomposed into different entities or units to facilitate parallelization of the design effort and modular processing at subsequent design steps. In addition, at step 202, the logic design may be debugged to correct logic, timing, and/or power issues in the design utilizing one or more debugging tools 154.

After a specification of the logical design is developed at logic design step 202, one or more verification tool(s) 154 are executed to verify the logical correctness of the logic design at logical verification step 204. The verification tool(s) 154 may include, for example, simulators, testbench generators, static HDL checkers, and formal verification tools. Synthesis tool(s) 156 can additionally be executed to transform the logic design represented in HDL files 160 into a netlist 162 in a logic synthesis step 206.

In a typical implementation, a netlist is a directed graph including a plurality of nodes representing “gates” and a plurality of edges representing “wires” (or “nets” or “signals”) between the gates. Gates have associated functions, such as constants, primary inputs, combinational logic (e.g., AND, OR, etc.), or sequential (or state-holding) elements (e.g., flip-flops, latches or registers). Hereafter, all sequential elements are referred to as “registers” for brevity. Certain gates are labeled as “primary outputs” of the netlist, which along with primary inputs represent interconnections to other logic components. Logic synthesis step 206 generally must preserve the behavior of primary outputs relative to primary inputs.

Generally, a netlist 162 can support arbitrary gate types with an arbitrary number of input and output pins. However, in some exemplary embodiments, netlist 162 is an AND/Inverter graph in which combinational gates are implemented with simple two-input AND gates, and inversions are implicit attributes of edges. In some cases, different netlist formats are utilized in different steps or stages of the integrated circuit design process. For example, integrated device manufacturer (IDM) netlist can be used in logic synthesis step 206, and a Design Activity Database (DADB) netlist can be used in the netlist verification step 208 (discussed below). Typically, each different netlist format supports a respective fixed set of gate types. Typically in a design-compilation flow for synthesis or for verification, netlists begin with higher-level gates (e.g., vectored multiplexors and adders). Subsequently, during compilation/model-build flow, the netlist gates are gradually decomposed into smaller, simpler gates, allowing fine-grained optimizations.

In a netlist, a “fanout-free logic cone” relative to a set of root gates R is a set of gates F which are topologically dominated by those root gates, that is, every path from any gate in F to next-state functions or primary outputs passes through R. Herein, gates at the input of the fanout-free logic cone are referred to as “leaves,” which can be arbitrary gates instead of “primary inputs” of the netlist. In the following description, aspects of the disclosed inventions rely upon identifying fanout-free logic cones relative to a single root gate.

Following step logic synthesis step 206, EDA tools 150 can be executed to perform a netlist verification step 208. In netlist verification, EDA tools 150 verify compliance of the netlist for correspondence to the design specified by the HDL files 160 and for compliance with any timing constraints of the design.

EDA tools 150 can then be executed to develop an implementation of the design as a physical integrated circuit. The development of the integrated circuit can begin with a floor planning step 210 in which a basic floor plan for the units and routing for the integrated circuit is constructed. Developing on the high-level physical layout provided by the floor plan, a more detailed physical layout is developed in placement and routing step 212. In step 212, standard cells, individual circuit components (e.g., transistors and capacitors), and routing are physically placed within the integrated circuit floorplan.

EDA tools 150 can additionally be executed to validate circuit function in an analysis and extraction step 214. In physical verification step 216, EDA tools 150 also verify satisfaction of manufacturing constraints, such as design rule check (DRC) constraints, power constraints, lithography constraints, etc., and further check that the integrated circuit conforms to the HDL design specification. EDA tools 150 further improve the geometry of the physical layout for purpose of manufacturing in a resolution enhancement step 218. Based on the final geometry determined at step 218, EDA tools 150 can generate, in tape-out and mask generation step 220, data sets detailing the design for lithographic masks utilized to fabricate the integrated circuit.

Following tape-out and mask generation step 220, lithographic masks can be utilized to fabricate integrated circuit chips in fabrication step 224. These integrated circuit chips can then be packaged and assembled on circuit cards and/or circuit boards, as depicted in packaging and assembly step 226. Thereafter, the process of FIG. 2 ends at block 228.

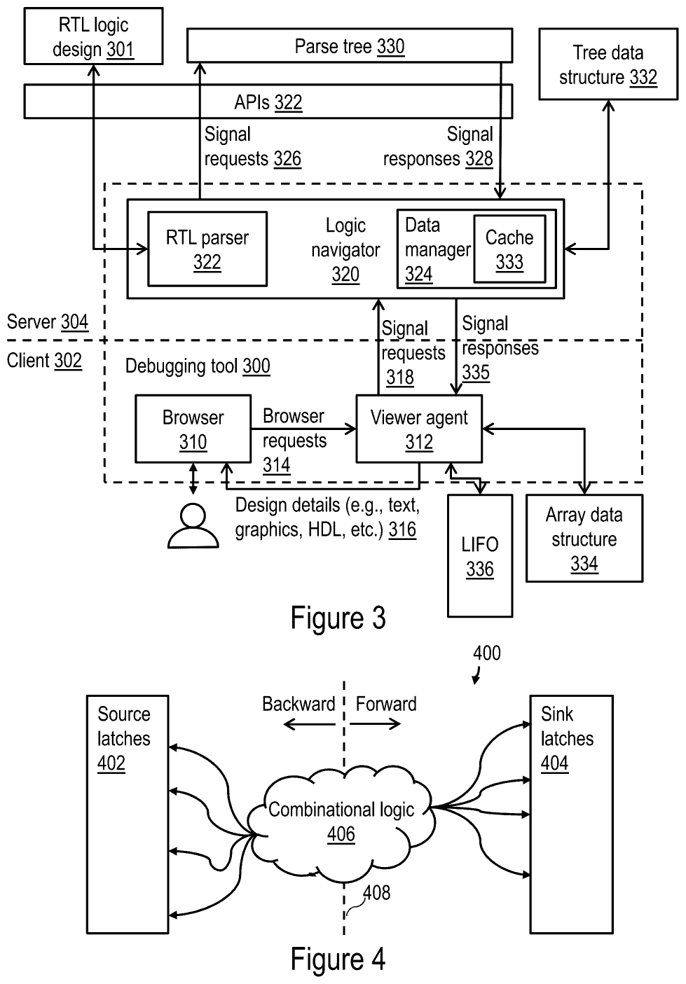

With reference now to FIG. 3, there is illustrated a high-level block diagram of an exemplary architecture of a debugging tool 300 that can be utilized to implement one of debugging tool(s) 154 in accordance with one or more embodiments. As noted above, debugging tool 300 can be executed to debug a RTL logic design 301 during one or more of the steps of the process given in FIG. 2. In this example, debugging tool 300 implements a client-server architecture that can advantageously be implemented in a cloud computing environment, such as computing environment 100 of FIG. 1, with microservices distributed across a client 302 and a server 304.

In the exemplary architecture, client 302, which can be, for example, a computer 101, an end user device 103 or a virtual machine 143, executes at least one instance of a browser 310 and a viewer agent 312. Browser 310 can be, for example, a conventional Internet browser or a special purpose browser. Browser 310 preferably provides an easy-to-use graphical user interface through which a user can enter, view, and/or update information regarding a RTL logic design 301, for example, in textual format, code format (e.g., in HDL), and/or graphical format. Viewer agent 312, which is communicatively coupled to browser 310 via a message-passing interface, receives browser requests 314 from browser 310 and provides design details 316 to browser 310 for presentation by browser 310 (e.g., in an unillustrated display device). As indicated, the design details 316 can include, for example, textual information, graphical information (e.g., logic design schematics, cone of influence tree diagrams, timing diagrams, power diagrams, etc.), and/or code defining the logic design (e.g., HDL code).

FIG. 3 further illustrates that, in the exemplary client-server architecture, server 304, which can be, for example, a computer 101, remote server 104, or virtual machine 143, executes a logic navigator 320. In the exemplary embodiment, logic navigator 320 can include multiple modules, including an RTL parser 322 and a data manager 324. RTL parser 322 is responsible for analyzing and elaborating RTL logic design 301 and for creating, via application program interfaces (APIs) 322, annotated parse tree 330 of RTL logic design 301. RTL parser 322 also utilizes APIs 322 to access parse tree 330 and to facilitate traversal of different types of nodes in RTL logic design 301 like assignments, instances, blocks, port maps, etc.

Data manager 324 reads annotated parse tree 330 and creates a tree data structure 332 representing RTL logic design 301 as a tree graph. This tree graph represents the different data paths starting at a signal of interest to its source or sink (e.g., a latch Q output can serve as a source of the tree graph, and a latch D input can serve as a sink). RTL constructs, such as assignment statements and port maps, instantiate the signals corresponding to the nodes of the tree graph between the root and leaves. In one preferred embodiment, tree data structure 332 comprises a JavaScript Object Notation (JSON)-formatted data structure, which optimizes the performance of rendering the tree graph and provides an intuitive representation of the constituent nodes. Each node of tree data structure 332 may store metadata, such as a node identifier, the signal name of interest, the filename of the HDL file defining the portion of RTL logic design 301 containing the signal of interest, the statement from the HDL file declaring the signal of interest (e.g., signal declaration, assignment statement, portmap, etc.), the line number in the statement that declares the signal of interest, and any “children” of the node. The child or children of the node indicate the operands driven by (for the backward COI) or driving the COI (for the forward COI). To support quick response times, data manager 324 can maintain a cache 333 for storing recently and/or frequently accessed portions of tree data structure 332.

In operation, browser requests 314 generated by browser 310 based on user interaction can cause viewer agent 312 to generate signal requests 318 to logic navigator 320. Each signal request 318 identifies a signal of interest in RTL logic design 301. In response to a signal request 318, logic navigator 320, in turn, queries parse tree 330 via a signal request 326 passed through APIs 322. In response to the signal request 326, RTL parser 322 of logic navigator 320 obtains one or more signal responses 328 providing details regarding the forward and backward cones of influence of the signal of interest. Utilizing these details, data manager 324 constructs and/or elaborates tree data structure 332, as needed to represent the forward and backward cones of influence of the signal of interest. It should be noted that tree data structure 332 preferably persists between user sessions of the same user and sessions of multiple different users and thus can represent a greater scope of RTL logic design 301 than the portion navigated in the current session of an individual user.

Logic navigator 320 satisfies a signal request 318 of viewer agent 312 by passing to viewer agent 312 signal responses 335 containing a portion of the tree data structure 332 corresponding to the forward and/or backward COI(s) of the signal of interest. In response to signal responses 335, viewer agent 312 can store the COI information received in the signal responses 335 in a client-side array data structure 334 and pass design details 316 from the DOM entries to browser 310 for presentation. With this exemplary architecture, debugging tool 300 can accelerate signal responses 335 and the presentation of design details 316 by referring to information concerning a RTL logic design 301 obtained from prior requests of the same and/or different users.

As a user selects various nodes of RTL logic design 301 to explore, viewer agent 312 dynamically creates a last-in, first-out (LIFO) data structure 336 that logs the identity of each node traversed by the user. For example, on each node traversal, the current node's information, (e.g., an identifier of the object associated with the node) is pushed onto LIFO data structure 336. LIFO data structure 336 preferably enables a “step back” feature that allows a user, via inputs to browser 310, to retrace a path of node traversal from a current node in RTL logic design 301 back to an original node accessed in RTL logic design 301.

As noted above, debugging tool 300 enables intuitive and rapid traversal of the forward and backward cones of influence of a selected signal in a RTL logic design 301. FIG. 4 depicts a logical representation of a portion of a register-transfer level (RTL) logic design 301 including a set of source latches 402, a set of sink latches 404, and connecting combinational logic 406 (i.e., a set of logic gate primitives, such as AND, OR, etc.) in accordance with one or more embodiments. As indicated, combinational logic 406 may include a signal of interest 408 that is generated within combinational logic, for example, based on a Boolean combination of one or more input operands that can be traced backward to one or more source latches 402. Signal of interest 408 and/or other signals generated by combinational logic 406 can be traced forward to one or more sink latches 404. A first subset of combinational logic 406 traversed from signal of interest 408 to source latches 402 forms the backward COI of signal of interest 408, and a second subset of combinational logic 406 traversed forward from signal of interest 408 to sink latches forms the forward COI. As discussed further herein, in at least some preferred embodiments, debugging tool 300 supports the presentation of both a tree view of a register-transfer level (RTL) logic design and a deepest COI view illustrating traceback and trace forward of a signal from an arbitrary selected node within the RTL logic design 301 to the sets of latches 402, 404 that source or sink signals at the selected node.

In at least some preferred embodiments, viewer agent 312 of client 302 uses dynamic Document Object Model (DOM) elements in array data structure 334 to enable interactive user interface and user experience (UI/UX). For example, viewer agent 312 can enable a user to graphically collapse or expand RTL nodes using dynamically generated DOM elements. These DOM elements additionally facilitate presentation of detailed info regarding each DOM node. The UI can also present a user's history of node traversals, enabling the user to step forward (or backward) along a signal path from a selected node of interest within the RTL logic design to its related child nodes and also return back to the selected node. In at least some preferred embodiments, viewer agent 312 additionally supports the spawning of multiple browsers 310, reading and rendering content regarding the logic design using DOM events and asynchronous programming.

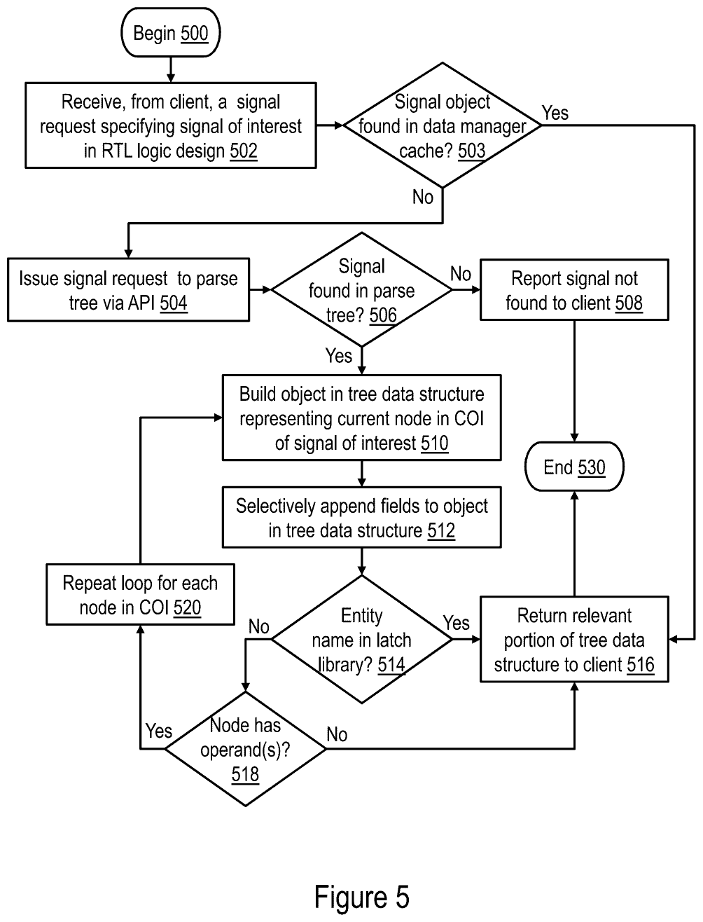

With reference now to FIG. 5, there is a high-level logical diagram of an exemplary process by which a server component of a debugging tool 300, such as logic navigator 320, services signal requests 318 of a client component of the debugging tool 300 in accordance with one or more embodiments. The process of FIG. 5 begins at block 500, for example, in response to logic navigator 320 receiving from client 302 a signal request 318 identifying a signal of interest in RTL logic design 301. Signal request 318 may additionally specify whether the forward or backward COI of the signal of interest is requested. The process then proceeds to block 502, which illustrates data manager 324 of logic navigator 320 determining whether or not cache 333 buffers a signal object corresponding to the signal of interest identified in the signal request 318. In response to a determination at block 503 that cache 333 buffers a signal object corresponding to the signal of interest, data manager 324 returns a signal response 335 including the signal object from cache 333, which in one preferred embodiment is a JSON-formatted data structure specifying the forward and/or backward COI(s) of the signal of interest (block 516). Thereafter, the process of FIG. 5 ends at block 530.

Returning to block 503, in response to data manager 324 determining that cache 333 does not contain a signal object corresponding to the signal of interest identified in the signal request 318, logic navigator 320 issues, to parse tree 330 via APIs 322, a signal request 326 including a textual input string from RTL logic design 301 (block 504). Signal request 326 requests return of the signal object corresponding to the textual input string. In response to logic navigator 320 receiving a signal response 328 to its signal request 326, logic navigator 320 determines at block 506 whether the signal response 328 indicates parse tree 330 includes the signal of interest. In response to determining at block 506 that signal response 328 indicates that parse tree 330 does not include the signal of interest, logic navigator 320 provides viewer agent 312 with a signal response 335 reporting that the signal of interest is not present in RTL logic design 301 (block 508). Viewer agent 312 may in turn furnish browser 310 with a suitable error message for display to the user. The process of FIG. 5 thereafter ends at block 530. If, however, logic navigator 320 determines at block 506 from signal response 328 that the signal of interest was located in parse tree 330, the process passes to block 510 and following blocks.

By the time the process reaches block 510, RTL parser 322 has preferably generated the entire parse tree 330 for RTL logic design 301, and data manager 324 is therefore able to construct a tree data structure 332 formed of interconnected objects representing nodes of RTL logic design 301 in the forward and/or backward COI(s) of the signal of interest. When data manager 324 first reaches block 510, data manager 324 begins by creating the object in tree data structure 332 representing the node in RTL logic design 301 at which the signal of interest is generated (block 510). In addition, data manager 324 appends to the signal object relevant metadata fields describing the corresponding node of RTL logic design 301, as described above (block 512). At block 514, data manager 324 checks whether or not the current object corresponds to a latch in RTL logic design 301 and, if so, whether the particular node has been previously visited (e.g., its unique hierarchy∥type_name is already present in tree data structure 332). In response to an affirmative determination at block 514, further construction of tree data structure 332 is paused until a next signal request 318, and the process passes to block 516. At block 516, data manager 324 returns a portion of tree data structure 332 (e.g., a JSON-formatted data structure) corresponding to the forward and/or backward COI(s) of the signal of interest to viewer agent 312 in a signal response 335. As noted above, based on the returned portion of tree data structure 332, viewer agent 312 may then provide design details 316 relevant to the signal of interest to browser 310 to enable their textual and/or graphical presentation to the user. Thereafter, the process of FIG. 5 ends at block 530.

Returning to block 514, based on a negative determination, data manager 324 additionally determines at block 518 whether or not the node of RTL logic design 301 corresponding to the current object has any operands, that is, signals influencing the state of the current node (for a backward COI) or influenced by the state of the current node (for the forward COI). In response to a negative determination at block 518, meaning that data manager 324 has reached the end of the COI, the process proceeds to block 516, which has been described. If, however, data manager 324 determines at block 518 that the node of RTL logic design 301 corresponding to the current object in tree data structure 332 has one or more operands, the process passes to block 520, which illustrates data manager 324 repeating the loop comprising blocks 510 to block 518 for the node of RTL logic design 301 corresponding to each operand until the full tree structure of the COI is built out in tree data structure 332. Following block 520, the process returns to block 510, which has been described.

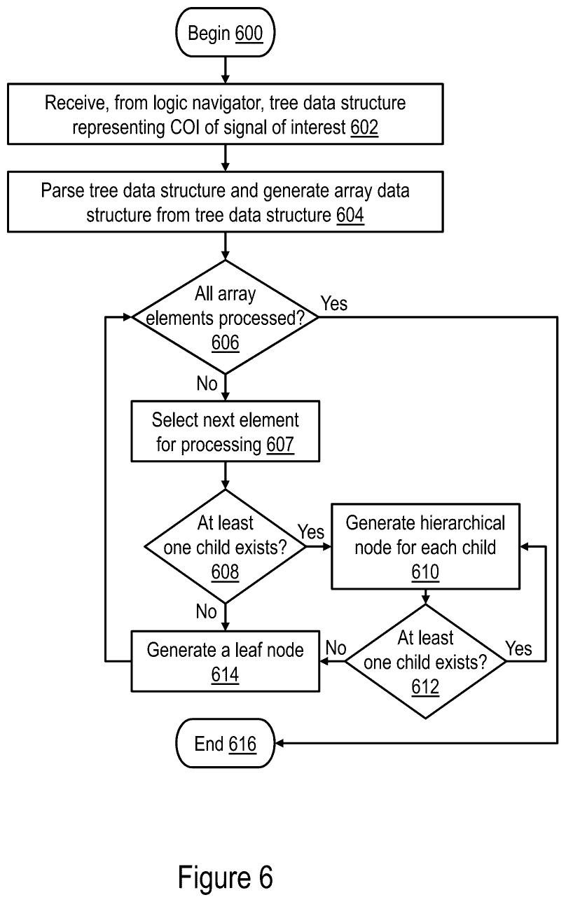

Referring now to FIG. 6, there is depicted a high-level logical diagram of an exemplary process by which a client component of a debugging tool 300 processes signal responses of a server component of debugging tool 300 in accordance with one or more embodiments. The process of FIG. 6 begins at block 600 and then proceeds to block 602, which illustrates viewer agent 312 receiving a signal response 335 from logic navigator 320. The signal response 335 includes a relevant portion of tree data structure 332 representing the COI of a signal of interest specified in a signal request 312 of viewer agent 312, as described above with reference to block 516 of FIG. 5.

At block 604, viewer agent 312 parses the tree data structure (e.g., a JSON-formatted data structure) returned in the signal response 335 and generates client-side array data structure 334. In one preferred embodiment, viewer agent 312 employs a Document Object Model (DOM) data structure for array data structure 334, optimizing the rendering performance of browser 310 and at the same time providing an intuitive representation of the COI(s) of the signal of interest. Following block 604, viewer agent 312 processes each array element in array data structure 334 in order to build out the content of array data structure 334 based on contents of the portion of tree data structure 332 received in signal response 335. This processing is represented in FIG. 6 by the processing loop including blocks 606 to 614.

Referring first to block 606, viewer agent 312 determines if it has processed all elements of array data structure 334 generated at block 604. In response to viewer agent 312 making an affirmative determination at block 606, processing of the signal response 335 by viewer agent 312 terminates at block 616. If, however, viewer agent 312 determines that fewer than all of the elements of array data structure 334 have been processed, viewer agent 312 selects a next unprocessed element of array data structure 334 for processing (block 607). Additionally, viewer agent 312 determines at block 608 whether or not the selected element has at least one child. Based on a negative determination at block 608, viewer agent 312 generates a leaf node in array data structure 334 representing a terminus of one traversal path through the COI of the signal of interest (block 614). In generating the leaf node, viewer agent 312 extracts information concerning the node from the signal response 335 (e.g., the JSON data structure) and populates the leaf node with the extracted information (e.g., as a DOM object). The process returns from block 614 to block 606, which has been described.

Based on viewer agent 312 determining at block 608 that the current element has at least one child, viewer agent 312 generates a hierarchical node in array data structure 334 representing a root or intermediate node in one path of traversal through the COI of the signal of interest (block 610). Again, viewer agent 312 extracts information concerning the node from the signal response 335 (e.g., the JSON data structure) and populates the hierarchical node with the extracted information (e.g., as a DOM object). As indicated at block 612, viewer agent 312 processes each child of the selected element of array data structure 334, creating for each descendant element either a hierarchical node (block 610) or leaf node (block 614). Viewer agent 312 continues processing elements in array data structure 334 until all unprocessed elements are exhausted; the process of FIG. 6 then terminates at block 616.

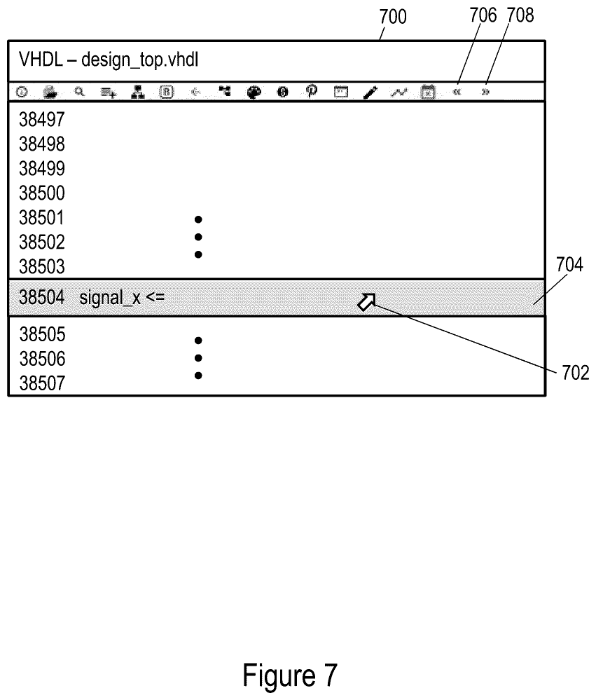

Having now described exemplary embodiments of the disclosed client-server debugging architecture, reference is made to FIGS. 7-13, which illustrate views of design details of RTL logic design 301 that may be presented to a user by viewer agent 312 via browser 310 in accordance with one or more embodiments.

Referring specifically to FIG. 7, there is illustrated an exemplary graphical user interface (GUI) window 700 in which HDL defining a portion of RTL logic design 301 can be viewed and edited in accordance with one or more embodiments. In the depicted use case, the user is viewing a HDL file named “design_top.vhdl,” which on line 38504 contains a portion of a statement referencing signal “signal_x”. If the user wishes to examine this signal in greater detail, the user can select the signal, for example, utilizing pointer 702 or a keyboard input. In response to this signal selection, line 38504 is highlighted, as generally indicated at reference numeral 704. The user can then explore the backward or forward COI of the signal of interest (i.e., signal_x) through additional selection of backward COI control 706 or forward COI control 708, respectively.

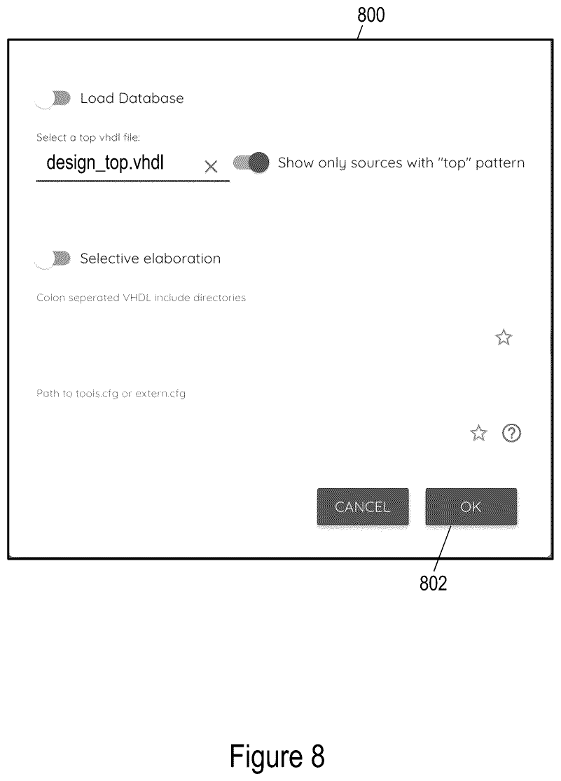

In response to selection, for example, of backward COI control 706, viewer agent 312 may present to the user via browser 310 a context window 800 as shown in FIG. 8. Context window 800 enables a user to access from a database a HDL file defining the context of the signal of interest. User selection of control 802 of context window 800 (e.g., utilizing pointer 702) generates a signal request 318 that results in viewer agent 312 generating an array data structure 334 describing the COI(s) of the signal interest in accordance with the processes described above with reference to FIGS. 5-6.

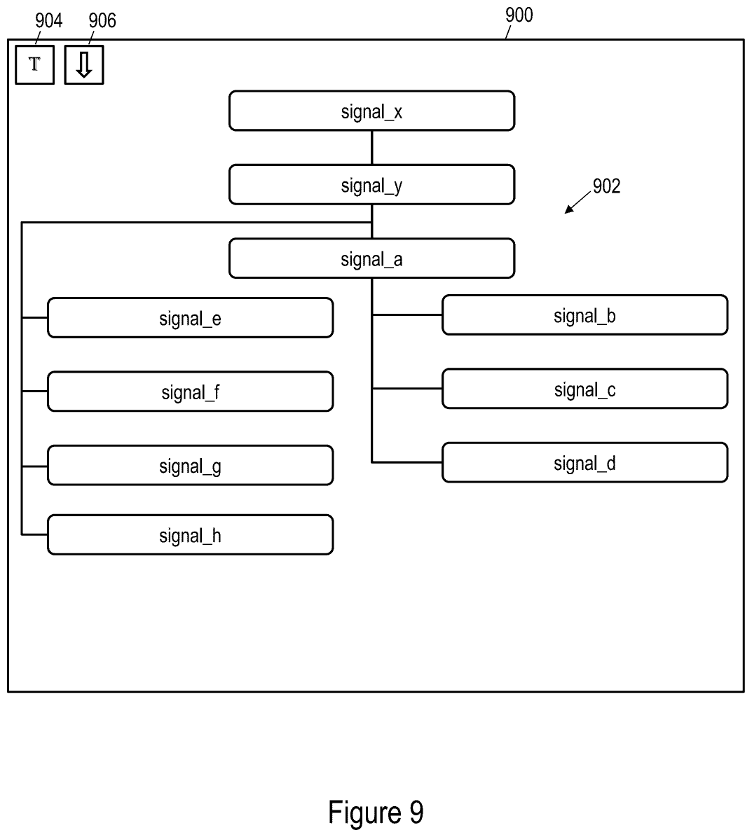

Following generation of array data structure 334, viewer agent 312 may cause browser 310 to present to the user a graphical representation of the requested COI of the signal of interest in a COI presentation window 900, as shown in FIG. 9. In the depicted exemplary embodiment of COI presentation window 900, the signal of interest (i.e., signal_x) is illustrated as the root of a tree structure 902 representing the backward COI of the signal of interest (and the parent/child relationships between the corresponding elements of array data structure 334). In this exemplary embodiment, COI presentation window 900 additionally includes a textual presentation control 904 and a deepest cone presentation control 906 that facilitate user navigation between various useful representations of the displayed COI.

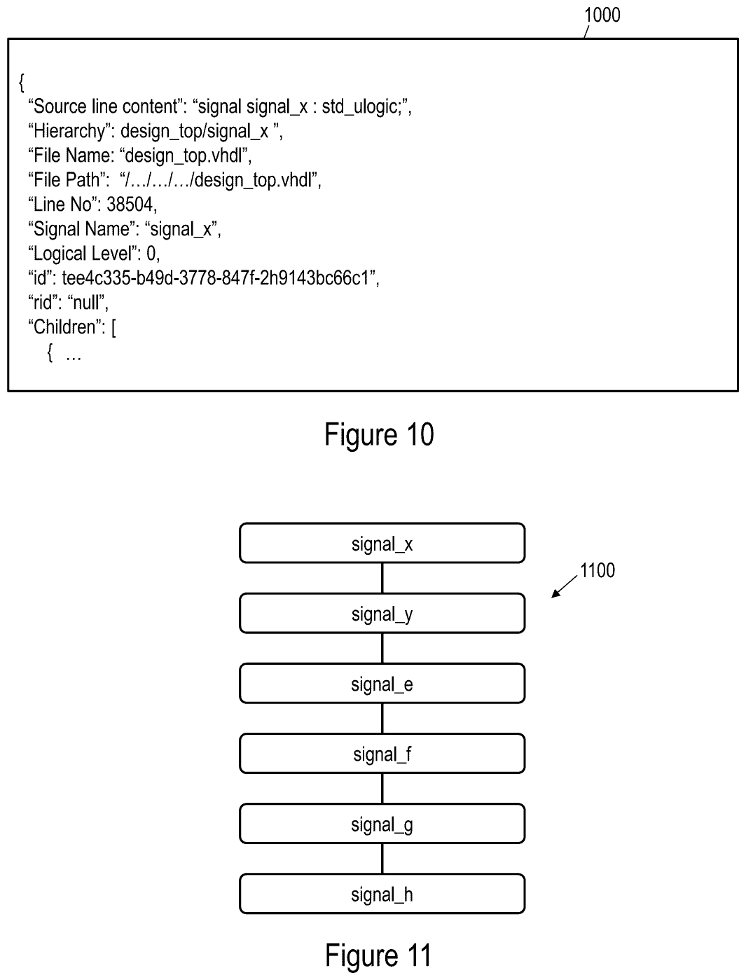

Thus, for example, in response to user selection of textual presentation control 904, viewer agent 312 may present a textual representation of the requested COI in a textual COI presentation window 1000, as shown in FIG. 10. In the illustrated embodiment, the textual presentation includes, for each signal in the COI, the HDL source line that declares the signal, the entity of the RTL logic design 301 in which the signal is found, the file name of the HDL file defining the entity, the file path to the HDL file in the file system, the line number of the HDL file at which the signal is instantiated, the signal name, the logical hierarchy level of the entity, a unique identifier (“id”) of the signal, and a listing of the child or children (if any) of the signal. In some embodiments, the contents of the textual presentation presented in textual presentation window 1000 can be similar to or the same as the contents of the JSON-formatted data structure returned by logic navigator 320 to viewer agent 312 in a signal response 335.

With reference to FIG. 11, in response to user selection of deepest cone presentation control 906 of COI presentation window 900, viewer agent 312 may present, within COI presentation window 900 or a different window, a graphical deepest cone tree structure 1100 representing only the deepest path of traversal through the COI of the signal of interest. Deepest cone tree structure 1100 presents the signal of interest as the root of deepest cone tree structure 1100, zero or more intermediate nodes (e.g., in this case, three), and a leaf node at the greatest depth of the backward COI.

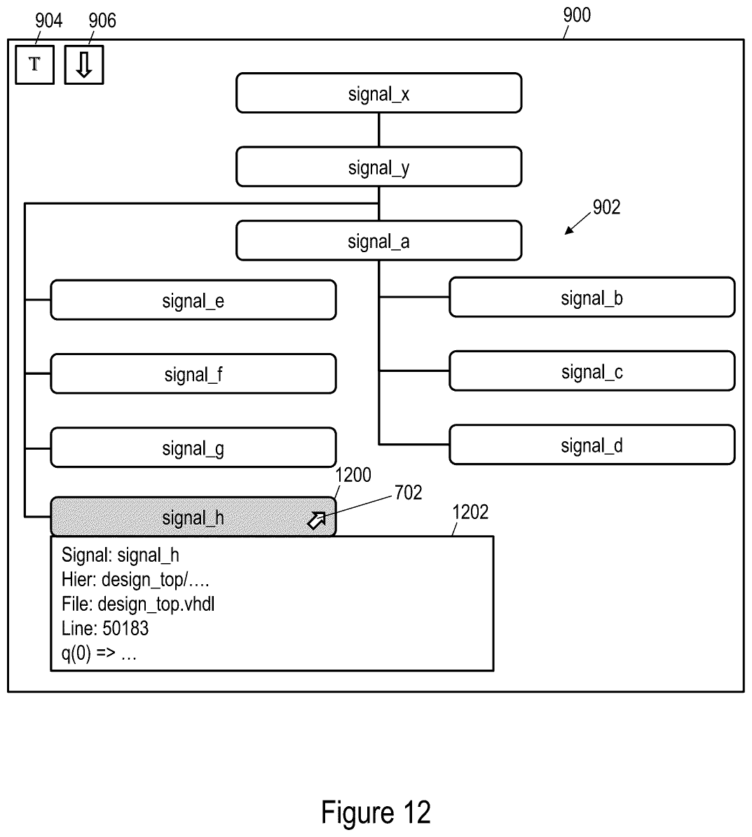

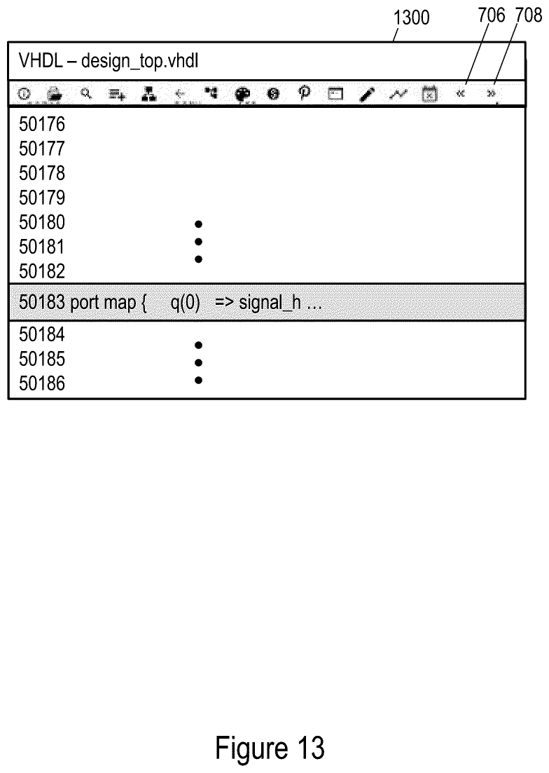

Referring now to FIG. 12, there is depicted a second view of COI presentation window 900 as described above with reference to FIG. 9. FIG. 12 further illustrates that a user may request presentation of details of a particular signal in the displayed tree structure 902, for example, by hovering pointer 702 over one of the nodes of tree structure 902. Thus, based on hovering pointer 702 over node 1200, which represents signal_h, viewer agent 312 presents via browser 310 a popup window 1202 providing details of the signal, including, for example, the signal name, its location in the design hierarchy, the filename of the HDL file in which the signal is declared, the line number in the HDL file at which the signal is declared, and the HDL statement that declares the signal. User selection of a node 1200 via browser 310 (e.g., by “clicking” on node 1200) invokes presentation by viewer agent 312 in browser 310 of the relevant portion of the HDL file in which the associated signal is declared, as depicted by the textual presentation provided in GUI window 1300 of FIG. 13. Thus, the user can easily and intuitively navigate between various textual, graphical, and code representations of signals in the forward and backward COIs of a signal of interest.

As has been described, according to one or more embodiments of a computer-implemented technique of debugging, a server receives, from a client, a signal request specifying a signal of interest in a register-transfer level (RTL) logic design. Based on the signal request, server processing circuitry of the server parses the RTL logic design and generates a tree data structure representing at least a cone of influence of the signal of interest. The server processing circuitry transmits to the client a signal response including a portion of the tree data structure. The portion of the tree data structure specifies, for each node among a plurality of nodes in the cone of influence of the signal of interest, at least a filename of a hardware description language (HDL) file in which a corresponding signal is instantiated, a line of HDL source code from the HDL file instantiating the corresponding signal, and any child of the node.

While the present invention has been particularly shown as described with reference to one or more preferred embodiments, it will be understood by those skilled in the art that various changes in form and detail may be made therein without departing from the spirit and scope of the invention.

The following definitions are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, system or apparatus that comprises a list of elements is not necessarily limited to only those elements but can include other elements not expressly listed or inherent to such composition, mixture, process, method, article, system or apparatus.

Additionally, the term “exemplary” is used herein to mean “serving as one example, instance or illustration. ” Any embodiment or design described herein as “exemplary” is not necessarily to be construed as preferred or advantageous over other embodiments or designs. The terms “at least one” and “one or more” shall be understood to include any integer number greater than or equal to one, and the term “plurality” shall be understood to include any integer number greater than or equal to two. The term “coupled” shall include both indirect connection and a direct connection, unless specified otherwise in a particular case. The terms “about,” “substantially,” “approximately,” and variations thereof, are intended to include the degree of error associated with measurement of the particular quantity based upon the equipment available at the time of filing the application. For example, “about” can include a range of ±10% or ±5%, or ±2% of a given value.

The figures described herein and the written description of specific structures and functions are not presented to limit the scope of what Applicants have invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. For the sake of brevity, conventional techniques related to making and using aspects of the invention(s) may or may not be described in detail herein, and many conventional implementation details are only mentioned briefly or are omitted entirely. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms. Lastly, the use of a singular term, such as, but not limited to, “a” is not intended as limiting of the number of items.

What is claimed is:

1. A computer-implemented method of debugging a logic design, the method comprising:
based on receiving, from a client, a signal request specifying a signal of interest in a register-transfer level (RTL) logic design, server processing circuitry of a server parsing the RTL logic design and generating a tree data structure representing at least a cone of influence of the signal of interest; and
the server processing circuitry transmitting to the client a signal response including a portion of the tree data structure, wherein the portion of the tree data structure specifies, for each node among a plurality of nodes in the cone of influence of the signal of interest, at least a filename of a hardware description language (HDL) file in which a corresponding signal is instantiated, a line of HDL source code from the HDL file instantiating the corresponding signal, and any child of the node.

2. The method of claim 1, wherein:
the signal request is a signal request of a first user made in a first debugging session; and
the transmitting includes transmitting the signal response in a second debugging session of a different second user.

3. The method of claim 1, wherein the parsing includes generating a parse tree of the RTL logic design.

4. The method of claim 1, wherein the signal response further includes an enumeration of a hierarchical entity in the RTL logic design in which the signal of interest is instantiated.

5. The method of claim 1, further comprising:
client processing circuitry of a client processing the portion of the tree data structure and generating at the client, from the portion of the tree data structure, a document object model (DOM) array data structure representing the cone of influence of the signal of interest.

6. The method of claim 5, further comprising:
based on the array data structure, the client processing circuitry presenting, via a browser, a graphical representation of the cone of influence and a textual representation of the cone of influence.

7. The method of claim 5, further comprising:
the client processing circuitry creating a last-in, first-out data structure storing a sequential history of traversal by a user of the array data structure.

8. A computer program product, comprising:
a storage device; and
program code stored within the storage device and executable by processing circuitry of a data processing system to cause the data processing system to perform:
based on receiving, from a client, a signal request specifying a signal of interest in a register-transfer level (RTL) logic design, a server parsing the RTL logic design and generating a tree data structure representing at least a cone of influence of the signal of interest; and
the server transmitting to the client a signal response including a portion of the tree data structure, wherein the portion of the tree data structure specifies, for each node among a plurality of nodes in the cone of influence of the signal of interest, at least a filename of a hardware description language (HDL) file in which a corresponding signal is instantiated, a line of HDL source code from the HDL file instantiating the corresponding signal, and any child of the node.

9. The program product of claim 8, wherein:
the signal request is a signal request of a first user made in a first debugging session; and
the transmitting includes transmitting the signal response in a second debugging session of a different second user.

10. The program product of claim 8, wherein the parsing includes generating a parse tree of the RTL logic design.

11. The program product of claim 8, wherein the signal response further includes an enumeration of a hierarchical entity in the RTL logic design in which the signal of interest is instantiated.

12. The program product of claim 8, wherein the program code further causes the client to perform:
processing the portion of the tree data structure and generating at the client, from the portion of the tree data structure, a document object model (DOM) array data structure representing the cone of influence of the signal of interest.

13. The program product of claim 12, wherein the program code further causes the client to perform:
based on the array data structure, presenting, via a browser, a graphical representation of the cone of influence and a textual representation of the cone of influence.

14. The program product of claim 12, wherein the program code further causes the client to perform:
creating a last-in, first-out data structure storing a sequential history of traversal by a user of the array data structure.

15. A data processing system, comprising:
processing circuitry; and
a storage device coupled to the processor set, wherein the storage device includes program code executable by the processing circuitry to cause the data processing system to perform:
based on receiving, from a client, a signal request specifying a signal of interest in a register-transfer level (RTL) logic design, a server parsing the RTL logic design and generating a tree data structure representing at least a cone of influence of the signal of interest; and
the server transmitting to the client a signal response including a portion of the tree data structure, wherein the portion of the tree data structure specifies, for each node among a plurality of nodes in the cone of influence of the signal of interest, at least a filename of a hardware description language (HDL) file in which a corresponding signal is instantiated, a line of HDL source code from the HDL file instantiating the corresponding signal, and any child of the node.

16. The data processing system of claim 15, wherein:
the signal request is a signal request of a first user made in a first debugging session; and
the transmitting includes transmitting the signal response in a second debugging session of a different second user.

17. The data processing system of claim 15, wherein the parsing includes generating a parse tree of the RTL logic design.

18. The data processing system of claim 15, wherein the signal response further includes an enumeration of a hierarchical entity in the RTL logic design in which the signal of interest is instantiated.

19. The data processing system of claim 18, wherein the program code further causes the client to perform:
processing the portion of the tree data structure and generating at the client, from the portion of the tree data structure, a document object model (DOM) array data structure representing the cone of influence of the signal of interest.

20. The data processing system of claim 18, wherein the program code further causes the client to perform:
based on the array data structure, presenting, via a browser, a graphical representation of the cone of influence and a textual representation of the cone of influence.
